(19) United States
(12) Patent Application Publication
(10) Pub. No.: US 2026/0066022 A1
(43) Pub. Date: Mar. 5, 2026

(54) MEMORY DEVICE CAPABLE OF SELECTIVELY INTERRUPTING POWER SUPPLY TO CIRCUIT PERFORMING SINGLE OPERATION

(71) Applicant: Samsung Electronics Co., Ltd., Suwon-si (KR)

(72) Inventors: Jiah JEON, Suwon-si (KR); Minsu LEE, Suwon-si (KR); Jungmin YOU, Suwon-si (KR); Beomsoon LEE, Suwon-si (KR)

(73) Assignee: Samsung Electronics Co., Ltd., Suwon-si (KR)

(21) Appl. No.: 19/291,127

(22) Filed: Aug. 5, 2025

(30) Foreign Application Priority Data
Sep. 5, 2024 (KR) 10-2024-0120944

(51) Int. Cl. G11C 29/12; G11C 29/14; G11C 29/18; G11C 29/44

(52) U.S. Cl. CPC G11C 29/12005; G11C 29/14; G11C 29/18; G11C 29/44; G11C 2029/1202; G11C 2029/1802

(57) ABSTRACT

A memory device that selectively interrupts power supply to a circuit performing a single operation includes a power source line, a ground source line, a power gating switch circuit, and a row decoder including word line driver circuits. The word line driver circuits include a first group and a second group based on a first most significant bit (MSB) signal among decoded row addresses. The power gating switch circuit connects the power source line and the ground source line to a first power supply voltage line and a first ground voltage line, respectively, of word line driver circuits in the first group in response to a first control signal and connects the power source line and the ground source line to the first power supply voltage line and the first ground voltage line, respectively, of word line driver circuits in the second group in response to a second control signal.

### CROSS-REFERENCE TO RELATED APPLICATION

This U.S. non-provisional application claims priority under 35 U.S.C. § 119 to Korean Patent Application No. 10-2024-0120944, filed on Sep. 5, 2024, in the Korean Intellectual Property Office, the disclosure of which is incorporated by reference herein in its entirety.

### BACKGROUND

Example embodiments of the inventive concepts relate to semiconductor memory devices that selectively interrupt power supply to a circuit performing a single operation.

The power budget of electronic devices includes power consumed by the memory systems of the electronic devices. Memory systems include memory devices having dynamic random-access memory (DRAM) implemented using multiple individual DRAM chips. Power consumption of DRAM may include dynamic power consumption while the DRAM is in operation and static power consumption while the DRAM is not in operation (is in standby mode). Higher capacity and higher performance DRAM may operate at a higher operating frequency and dynamic power consumption may increase. The static power consumption may be due to leakage current in the transistors of the DRAM. The leakage current may include subthreshold leakage current, gate-tunneling leakage current, gate-induced drain leakage (GIDL) current, and junction tunneling leakage current. It may be beneficial to reduce or minimize power consumption in the high capacity and/or high performance of DRAM devices.

### SUMMARY

Example embodiments of the inventive concepts provide a memory device that is configured to selectively interrupt power supply to a circuit performing a single operation.

According to some example embodiments of the inventive concepts, a memory device may include a power source line, a ground source line, and a row decoder connected to a plurality of word lines connected to memory cells and including word line driver circuits configured to select a word line corresponding to decoded row addresses. The word line driver circuits may be driven by a power supply voltage supplied to a first power supply voltage line and a ground voltage supplied to a first ground voltage line. The word line driver circuits may be divided, based on a first most significant bit (MSB) signal, into a first group and a second group. The first MSB signal may correspond to an MSB signal among the decoded row addresses. The memory device may also include a power gating switch circuit configured to connect the power source line and the ground source line to the first power supply voltage line and the first ground voltage line, respectively, of word line driver circuits in the first group in response to a first control signal. The power gating switch circuit may also be configured to connect the power source line and the ground source line to the first power supply voltage line and the first ground voltage line, respectively, of word line driver circuits in the second group in response to a second control signal.

According to some example embodiments of the inventive concepts, a memory device may include a power source line, a ground source line, and a column decoder connected to a plurality of bit lines connected to memory cells and including column selection line drivers configured to select a bit line corresponding to decoded column addresses. The column selection line drivers each include a first driver circuit and a second driver circuit each configured to be driven by a power supply voltage supplied to a first power supply voltage line and a ground voltage supplied to a first ground voltage line. The first driver circuit and the second driver circuit may be activated in response to a first MSB signal corresponding to an MSB signal among the decoded column addresses obtained by excluding decoded column addresses addressing the column selection line drivers. The memory device may further include a power gating switch circuit configured to connect the power source line and the ground source line to the first power supply voltage line and the first ground voltage line, respectively, of the first driver circuit in response to a first control signal and configured to connect the power source line and the ground source line to the first power supply voltage line and the first ground voltage line, respectively, of the second driver circuit in response to a second control signal.

According to some example embodiments of the inventive concepts, a memory device may include first and second power source lines, first and second ground source lines, and a row decoder connected to a plurality of word lines connected to memory cells and including word line driver circuits configured to select a word line corresponding to decoded row addresses. The word line driver circuits are configured to be driven by a power supply voltage supplied to a first power supply voltage line and a ground voltage supplied to a first ground voltage line and the word line driver circuits are divided, based on a first MSB signal, into a first group and a second group. The first MSB signal corresponds to an MSB signal among the decoded row addresses. The memory device also includes a column decoder connected to a plurality of bit lines connected to the memory cells and including column selection line drivers configured to select a bit line corresponding to decoded column addresses. The column selection line drivers each include a first driver circuit and a second driver circuit each configured to be driven by the power supply voltage supplied to a second power supply voltage line and the ground voltage supplied to a second ground voltage line. The first driver circuit and the second driver circuit are activated based on a second MSB signal corresponding to an MSB signal among the decoded column addresses obtained by excluding decoded column addresses addressing the column selection line drivers. The memory device also includes a power gating switch circuit configured to connect the first power source line and the first ground source line to the first power supply voltage line and the first ground voltage line, respectively, of word line driver circuits in the first group in response to a first control signal, configured to connect the first power source line and the first ground source line to the first power supply voltage line and the first ground voltage line, respectively, of word line driver circuits in the second group in response to a second control signal, configured to connect the second power source line and the second ground source line to the second power supply voltage line and the second ground voltage line, respectively, of the first driver circuit in response to a third control signal, and configured to connect the second power source line and the second ground source line to the second power supply voltage line and the second ground voltage line, respectively, of the second driver circuit in response to a fourth control signal.

### BRIEF DESCRIPTION OF THE DRAWINGS

The above and other aspects and features of the example embodiments will more clearly understood from the following detailed description taken in conjunction with the accompanying drawings.

FIG. 1 illustrates a memory device, according to some example embodiments.

FIG. 2 is a block diagram illustrating a row decoder of FIG. 1, according to some example embodiments.

FIGS. 3A, 3B, 3C, and 3D are circuit diagrams illustrating a main word line driver circuit and a sub word line driver circuit of FIG. 2, according to some example embodiments.

FIG. 4 is a diagram illustrating a row decoder, according to some example embodiments.

FIGS. 5A, 5B, 5C, 5D, 5E, 5F, and 5G are diagrams illustrating control logic circuits, according to some example embodiments.

FIGS. 6A and 6B are block diagrams illustrating a column decoder of FIG. 1, according to some example embodiments.

FIGS. 7A, 7B, 7C, 7D, and 7E are diagrams illustrating control logic circuits, according to some example embodiments.

FIG. 8 is a block diagram of a system illustrating an electronic apparatus including a memory apparatus, according to some example embodiments.

### DETAILED DESCRIPTION

Memory devices may include different power-saving methods. For example, a dynamic random-access memory (DRAM) may operate in a power-down mode in which internal circuits and/or components not in use are deactivated or powered down. In the power-down mode, some elements, for example, transistors, of the DRAM may continue to consume power due to standby or leakage current. In order to reduce standby power consumption, a power gating switch may be used. DRAM may reduce dynamic power consumption by using a power gating switch that may selectively interrupt power supply to internal circuit devices performing a single operation according to a received command (e.g., an active, a read, or a write command). The power gating switch may be between a power source and at least one downstream logic element. When the power gating switch is turned on, power may be supplied to the downstream logic element. When the power gating switching is turned off, power supply to the downstream logic element may be interrupted or reduced or minimized. The power gating switch may limit power consumption of the DRAM. Hereinafter, memory devices capable of selectively interrupting power supply to a circuit (e.g., a row decoder or a column decoder) performing a single operation are described.

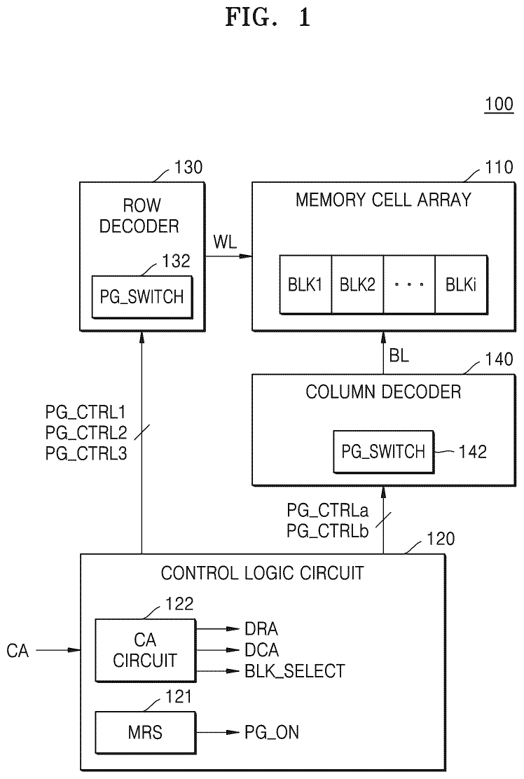

FIG. 1 illustrates a memory device 100 according to some example embodiments.

Referring to FIG. 1, a memory device 100 may include a memory cell array 110, a control logic circuit 120, a row decoder 130, and/or a column decoder 140.

The memory cell array 110 may include a plurality of word lines WL, a plurality of bit lines BL, and a plurality of memory cells at intersections between the word lines WL and the bit lines BL and may be divided into a plurality of memory blocks BLK1 to BLKi (where “i” is an integer of at least 2). The memory blocks (also referred to as memory banks) BLK1 to BLKi may each be divided into logical and/or physical groups from the perspective of addressing/memory access by a memory controller.

The control logic circuit 120 may control operations of the memory device 100. The control logic circuit 120 may include a mode register set (MRS) 121 that may set a plurality of operation options of the memory device 100 and a command address (CA) circuit 122 that may receive a command address CA externally from a memory controller connected to the memory device 100. The MRS 121 may store a power gating on signal PG_ON that may be used to set a power gating operation of the memory device 100. The CA circuit 122 may capture and/or decode a command operand and an address operand from the command address CA and generate a block selection signal BLK_SELECT for selecting a memory block on which a command is executed, a decoded row address DRA, and a decoded column address DCA. The block selection signal BLK_SELECT, the decoded row address DRA, and the decoded column address DCA may be provided to the row decoder 130 and the column decoder 140.

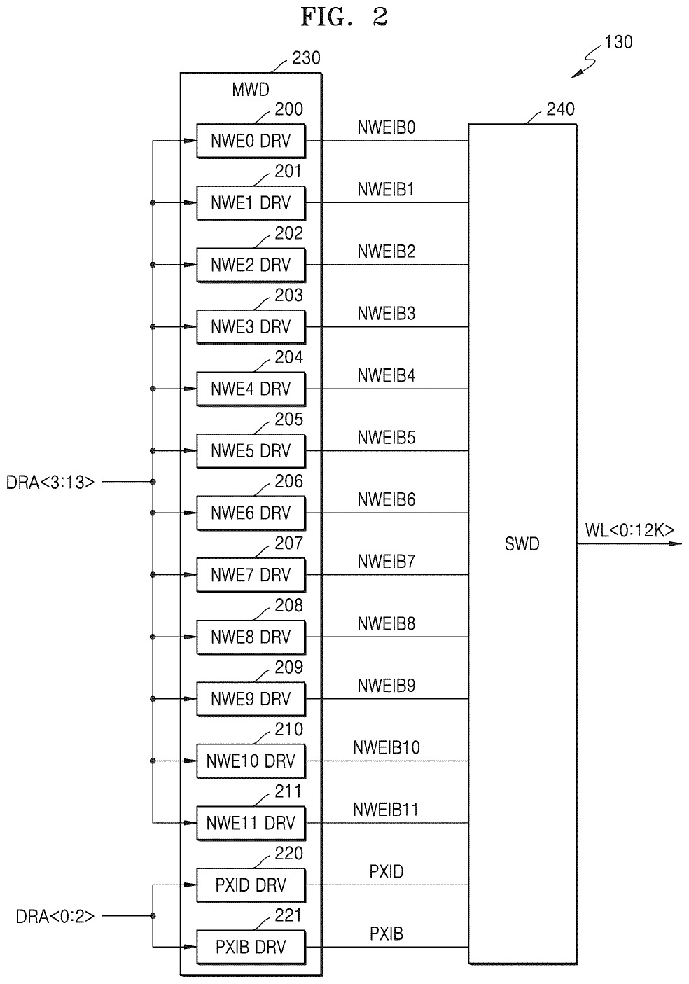

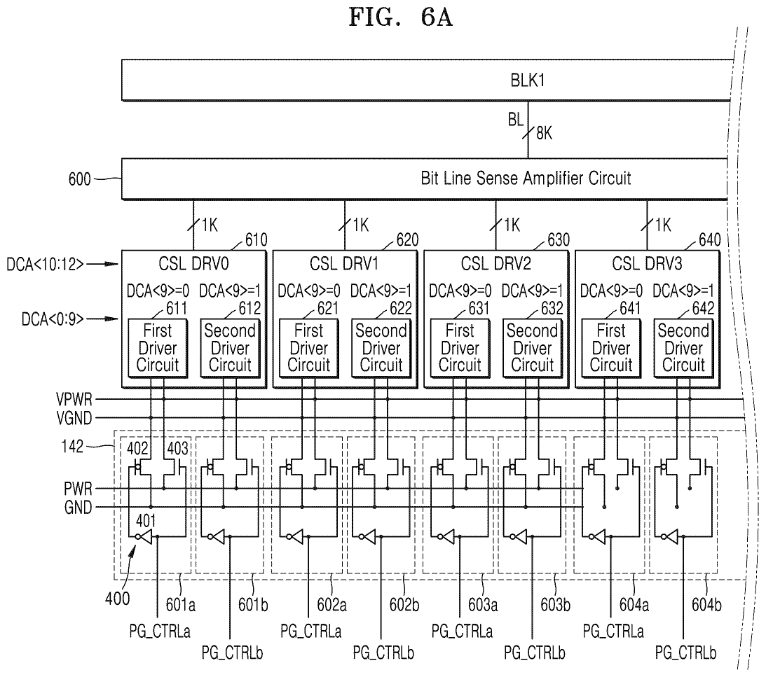

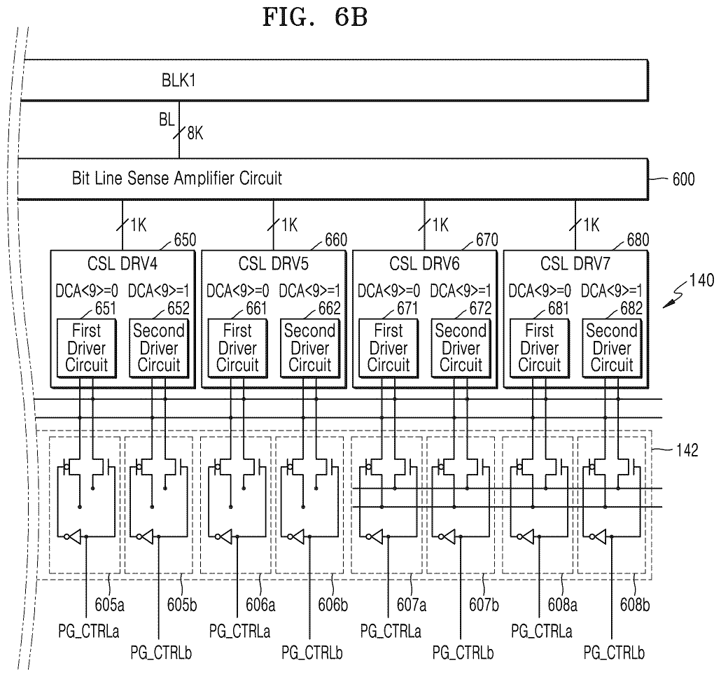

The control logic circuit 120 may generate first to third control signals PG_CTRL1, PG_CTRL2, and PG_CTRL3 that may control a power gating switch circuit 132 to place one or more circuits (e.g., one or more of the first to twelfth main word line drive signal generation circuits 200 to 211 in FIG. 2) of the row decoder 130 in a powered-off state. The control logic circuit 120 may generate first and second control signals PG_CTRLa and PG_CTRLb that may control a power gating switch circuit 142 to place one or more circuits (e.g., one or more of the first driver circuits 611, 621, 631, 641, 651, 661, 671, and 681 and second driver circuits 612, 622, 632, 642, 652, 662, 672, and 682 in FIGS. 6A and 6B) of the column decoder 140 in a powered-off state.

The row decoder 130 may include word line driver circuits (FIG. 2) which may select a word line WL corresponding to the decoded row address DRA with respect to a memory block selected from among the memory blocks BLK1 to BLKi. The row decoder 130 may place some (e.g., one or more) word line driver circuits in a powered-off state using the power gating switch circuit 132, thereby reducing or minimizing power consumption.

The column decoder 140 may include column selection line drivers (FIGS. 6A and 6B) which may select bit lines BL corresponding to the decoded column address DCA with respect to the selected memory block. The column decoder 140 may place some (e.g., one or more) column selection line drivers in a powered-off state using the power gating switch circuit 142, thereby reducing or minimizing power consumption.

FIG. 2 is a block diagram illustrating the row decoder 130 in FIG. 1. For the purposes of discussion, each of the memory blocks BLK1 to BLKi in FIG. 1 may include, for example, 12K word lines WL according to the configuration of (or based on) fourteen row address signals RA<0:13>. However, this is just an example and is not intended to limit the example embodiments. In some example embodiments, each of the memory blocks BLK1 to BLKi may include 16K or 32K word lines WL according to the configuration of (or based on) fourteen row address signals RA<0:13> or fifteen row address signals RA<0:14>. For convenience of description, it is described below that a memory block refers to the memory block BLK1.

Referring to FIGS. 1 and 2, the row decoder 130 may select a word line WL corresponding to the decoded row address DRA with respect to the memory block BLK1. The row decoder 130 may include a main word line driver (MWD) circuit 230 and a sub word line driver (SWD) circuit 240. The main word line driver circuit 230 may include first to twelfth main word line drive signal generation circuits 200 to 211 and first and second sub word line drive signal generation circuits 220 and 221. The first to twelfth main word line drive signal generation circuits 200 to 211 may respectively generate first to twelfth main word line drive signals NWEIB0 to NWEIB11 based on signals in a most significant bit (MSB) group among the row address signals RA<0:13>. Among the row address signals RA<0:13>, the signals in the MSB group may be set to an RA<3:13> row address. The RA<3:13> row address may be decoded by the CA circuit 122 and provided, as a decoded row address (expressed as a DRA<3:13> row address), to the first to twelfth main word line drive signal generation circuits 200 to 211.

In some example embodiments, the first main word line drive signal generation circuit 200 may generate the first main word line drive signal NWEIB0 according to the DRA<3:13> row address. The second main word line drive signal generation circuit 201 may generate the second main word line drive signal NWEIB1 according to the DRA<3:13> row address. The third main word line drive signal generation circuit 202 may generate the third main word line drive signal NWEIB2 according to the DRA<3:13> row address. The fourth main word line drive signal generation circuit 203 may generate the fourth main word line drive signal NWEIB3 according to the DRA<3:13> row address. The fifth main word line drive signal generation circuit 204 may generate the fifth main word line drive signal NWEIB4 according to the DRA<3:13> row address. The sixth main word line drive signal generation circuit 205 may generate the sixth main word line drive signal NWEIB5 according to the DRA<3:13> row address. The seventh main word line drive signal generation circuit 206 may generate the seventh main word line drive signal NWEIB6 according to the DRA<3:13> row address. The eighth main word line drive signal generation circuit 207 may generate the eighth main word line drive signal NWEIB7 according to the DRA<3:13> row address. The ninth main word line drive signal generation circuit 208 may generate the ninth main word line drive signal NWEIB8 according to the DRA<3:13> row address. The tenth main word line drive signal generation circuit 209 may generate the tenth main word line drive signal NWEIB9 according to the DRA<3:13> row address. The eleventh main word line drive signal generation circuit 210 may generate the eleventh main word line drive signal NWEIB10 according to the DRA<3:13> row address. The twelfth main word line drive signal generation circuit 211 may generate the twelfth main word line drive signal NWEIB11 according to the DRA<3:13> row address.

In some example embodiments, the main word line driver circuit 230 may change decoding that generates a plurality of main word line drive signals NWEIBn-1 (where “n” is a natural number), based on the number of bits (e.g., 11 or 12) in signals in the MSB group among row address signals according to the configurations of various numbers of (e.g., 16K and 32K) word lines.

The main word line driver circuit 230 may generate first and second sub word line drive signals PXID and PXIB, based on signals in a least significant bit (LSB) group among the row address signals RA<0:13>. Among the row address signals RA<0:13>, the signals in the LSB group may be set to an RA<0:2> row address. The RA<0:2> row address may be decoded by the CA circuit 122 and provided, as a decoded row address (expressed as a DRA<0:2> row address), to the first and second sub word line drive signal generation circuits 220 and 221. The first sub word line drive signal generation circuit 220 may generate the first sub word line drive signal PXID according to the DRA<0:2> row address. The second sub word line drive signal generation circuit 221 may generate the second sub word line drive signal PXIB according to the DRA<0:2> row address.

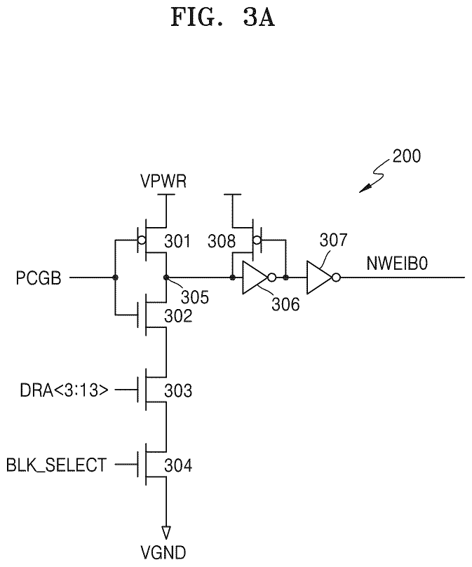

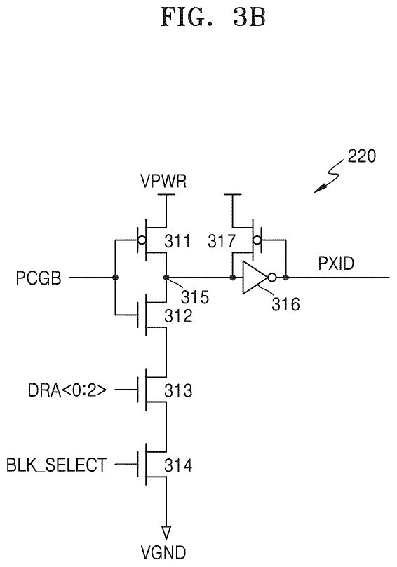

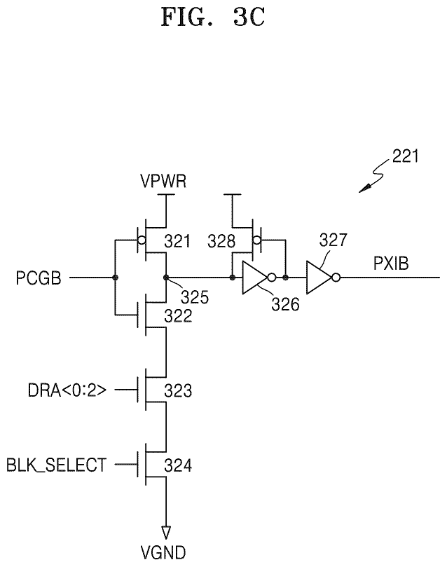

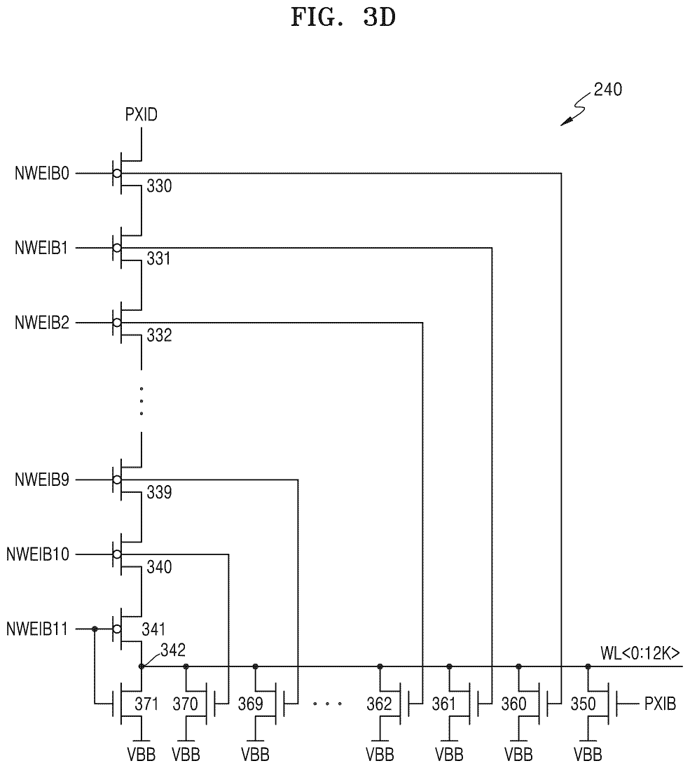

FIGS. 3A to 3D are circuit diagrams illustrating the main word line driver circuit 230 and the sub word line driver circuit 240 of FIG. 2. FIG. 3A is a circuit diagram illustrating the first main word line drive signal generation circuit 200 among the first to twelfth main word line drive signal generation circuits 200 to 211 of the main word line driver circuit 230. FIGS. 3B and 3C are circuit diagrams respectively illustrating the first sub word line drive signal generation circuit 220 and the second sub word line drive signal generation circuit 221. FIG. 3D is a circuit diagram illustrating the sub word line driver circuit 240. The description of the first main word line drive signal generation circuit 200 may also be applied to the second to twelfth main word line drive signal generation circuits 201 to 211.

Referring to FIG. 3A, the first main word line drive signal generation circuit 200 may include first to fourth transistors 301 to 304 connected in series between a line of a first power supply voltage VPWR (or first power supply voltage line) and a line of a first ground voltage VGND (or first ground voltage line), first and second inverters 306 and 307 connected in series to a connection node 305 of the first and second transistors 301 and 302, and a fifth transistor 308 connected between the line of the first power supply voltage VPWR and the connection node 305 of the first and second transistors 301 and 302. The first to fourth transistors 301 to 304 may represent a NAND logic circuit. The first transistor 301 may include a P-type metal-oxide semiconductor (PMOS) transistor having a gate receiving a precharge signal PCGB. The second transistor 302 may include an N-type MOS (NMOS) transistor having a gate receiving the precharge signal PCGB.

In some example embodiments, the precharge signal PCGB may be provided by the control logic circuit 120 based on a precharge command and may act as a signal activating the row decoder 130. The row decoder 130 may be activated by the precharge signal PCGB at a logic high level and deactivated by the precharge signal PCGB at a logic low level.

The third transistor 303 may include an NMOS transistor having a gate receiving the DRA<3:13> row address. The fourth transistor 304 may include an NMOS transistor having a gate receiving the block selection signal BLK_SELECT. The block selection signal BLK_SELECT may be provided to select one memory block from among the memory blocks BLK1 to BLKi. For example, a first block selection signal at a logic high level may be provided to select the memory block BLK1.

The first and second inverters 306 and the 307 connected in series to the connection node 305 of the first and second transistors 301 and 302 may output the first main word line drive signal NWEIB0. The fifth transistor 308 may include a PMOS transistor having a gate receiving an output of the first inverter 306 and may be referred to as a keeper transistor that stably maintains the output of the first inverter 306.

The first main word line drive signal generation circuit 200 may output a plurality of first main word line drive signals NWEIB0 in response to the DRA<3:13> row address. The signal configuration of the DRA<3:13> row address may include three cases (e.g., 00, 01, and 10) according to row address signals RA<12:13> in the MSB group. For example, the first main word line drive signal NWEIB0 may be activated according to a DRA<12:13> row address signal “00” and a DRA[4:11] row address signal.

In some example embodiments, like the first main word line drive signal generation circuit 200, the second to fourth main word line drive signal generation circuits 201 to 203 may be activated based on the DRA<12:13> row address signal “00”. The fifth to eighth main word line drive signal generation circuits 204 to 207 may be activated based on a DRA<12:13> row address signal “01”. The ninth to twelfth main word line drive signal generation circuits 208 to 211 may be activated based on a DRA<12:13> row address signal “10”.

Referring to FIG. 3B, the first sub word line drive signal generation circuit 220 may include first to fourth transistors 311 to 314 connected in series between the line of the first power supply voltage VPWR and the line of the first ground voltage VGND, an inverter 316 connected to a connection node 315 of the first and second transistors 311 and 312, and a fifth transistor 317 connected between the line of the first power supply voltage VPWR and the connection node 315 of the first and second transistors 311 and 312. The first to fourth transistors 311 to 314 may represent a NAND logic circuit. The first transistor 311 may include a PMOS transistor having a gate receiving the precharge signal PCGB. The second transistor 312 may include an NMOS transistor having a gate receiving the precharge signal PCGB. The third transistor 313 may include an NMOS transistor having a gate receiving the DRA<0:2> row address. The fourth transistor 314 may include an NMOS transistor having a gate receiving the block selection signal BLK_SELECT. The inverter 316 may output the first sub word line drive signal PXID. The fifth transistor 317 may include a PMOS transistor having a gate receiving an output of the inverter 316 and may be referred to as a keeper transistor that stably maintains the output of the inverter 316.

The first sub word line drive signal generation circuit 220 may include eight elements respectively outputting eight cases of the first sub word line drive signal PXID in response to the DRA<0:2> row address. There may be eight cases (i.e., 000, 001, 010, 011, 100, 101, 110, and 111) for the signal configuration of the DRA<0:2> row address, and thus, there may also be eight cases for the first sub word line drive signal PXID that is activated. In other words, one of signals PXID<0>, PXID<1>, PXID<2>, PXID<3>, PXID<4>, PXID<5>, PXID<6>, and PXID<7> may be activated to a logic high level according to the DRA<0:2> row address. The first sub word line drive signal PXID at the logic high level may have the level of the first power supply voltage VPWR and may be provided to the sub word line driver circuit 240 connected to each of the memory blocks BLK1 to BLKi.

Referring to FIG. 3C, the second sub word line drive signal generation circuit 221 may include first to fourth transistors 321 to 324 connected in series between the line of the first power supply voltage VPWR and the line of the first ground voltage VGND, first and second inverters 326 and 327 connected in series to a connection node 325 of the first and second transistors 321 and 322, and a fifth transistor 328 connected between the line of the first power supply voltage VPWR and the connection node 325 of the first and second transistors 321 and 322. The first to fourth transistors 321 to 324 may represent a NAND logic circuit. The second sub word line drive signal generation circuit 221 may be configured in the same or similar manner as the first sub word line drive signal generation circuit 220 of FIG. 3B. The second sub word line drive signal PXIB is output by the first and second inverters 326 and 327 connected in series to the connection node 325 of the first and second transistors 321 and 322. The second sub word line drive signal PXIB may have an opposite logic level to the first sub word line drive signal PXID.

The second sub word line drive signal generation circuit 221 may include eight elements respectively outputting eight cases of the second sub word line drive signal PXIB in response to the DRA<0:2> row address. There may be eight cases (i.e., 000, 001, 010, 011, 100, 101, 110, and 111) for the signal configuration of the DRA<0:2> row address, and thus, there may also be eight cases for the second sub word line drive signal PXIB that is activated. In other words, one of signals PXIB<0>, PXIB<1>, PXIB<2>, PXIB<3>, PXIB<4>, PXIB<5>, PXIB<6>, and PXIB<7> may be activated to a logic low level according to the DRA<0:2> row address. The second sub word line drive signal PXIB at the logic low level may have the level of the first ground voltage VGND and may be provided to the sub word line driver circuit 240 connected to each of the memory blocks BLK1 to BLKi.

Referring to FIG. 3D, the sub word line driver circuit 240 may include a plurality of transistors 330 to 341, 360 to 371, and 350. The transistors 330 to 341 may include PMOS transistors connected in series between a line of the first sub word line drive signal PXID and a connection node 342. The connection node 342 may be or define a connection of the transistors 360 to 371 and the transistor 350. The first main word line drive signal NWEIB0 may be input to the gate of the transistor 330, the second main word line drive signal NWEIB1 may be input to the gate of the transistor 331, and the third main word line drive signal NWEIB2 may be input to the gate of the transistor 332. The tenth main word line drive signal NWEIB9 may be input to the gate of the transistor 339, the eleventh main word line drive signal NWEIB10 may be input to the gate of the transistor 340, and the twelfth main word line drive signal NWEIB11 may be input to the gate of the transistor 341. For clarity of illustration, transistors 333, 334, 335, 336, 337, and 338 connected in series between the transistors 332 and 339 and having gates respectively receiving the fourth to ninth main word line drive signals NWEIB3, NWEIB4, NWEIB5, NWEIB6, NWEIB7, and NWEIB8 are omitted from FIG. 3D.

The transistors 360 to 371 and 350 may include NMOS transistors connected in parallel between a line of a negative voltage VBB and the connection node 342. The first main word line drive signal NWEIB0 may be input to the gate of the transistor 360, the second main word line drive signal NWEIB1 may be input to the gate of the transistor 361, and the third main word line drive signal NWEIB2 may be input to the gate of the transistor 362. The tenth main word line drive signal NWEIB9 may be input to the gate of the transistor 369, the eleventh main word line drive signal NWEIB10 may be input to the gate of the transistor 370, and the twelfth main word line drive signal NWEIB11 may be input to the gate of the transistor 371. For clarity of illustration, transistors connected in parallel between the line of the negative voltage VBB and the connection node 342 between the transistors 360 to 371 and the transistor 350 and having gates respectively receiving the fourth to ninth main word line drive signals NWEIB3, NWEIB4, NWEIB5, NWEIB6, NWEIB7, and NWEIB8 are omitted.

The transistor 350 may include an NMOS transistor having a source connected to the line of the negative voltage VBB, a drain connected to the connection node 342 between the transistors 360 to 371 and the transistor 350, and a gate receiving the second sub word line drive signal PXIB. The connection node 342 between the transistors 360 to 371 and the transistor 350 may be connected to word lines WL<0:12K> of the memory block BLK1. The transistors 330 to 341, 360 to 371, and 350 of the sub word line driver circuit 240 may be implemented as a NOR logic circuit.

The sub word line driver circuit 240 may include 12K elements respectively connected to the first to twelfth main word line drive signals NWEIB0 to NWEIB11, the first sub word line drive signal PXID, and the second sub word line drive signal PXIB. The sub word line driver circuit 240 may select and activate one of the 12K word lines WL<0:12K> to a logic high level in response to the logic low level of the activated first to twelfth main word line drive signals NWEIB0 to NWEIB11, the logic high level of the activated first sub word line drive signal PXID, and the logic low level of the activated second sub word line drive signal PXIB. The selected word line among the word lines WL<0:12K> may be activated to the level of the first power supply voltage VPWR of the first sub word line drive signal PXID at the logic high level.

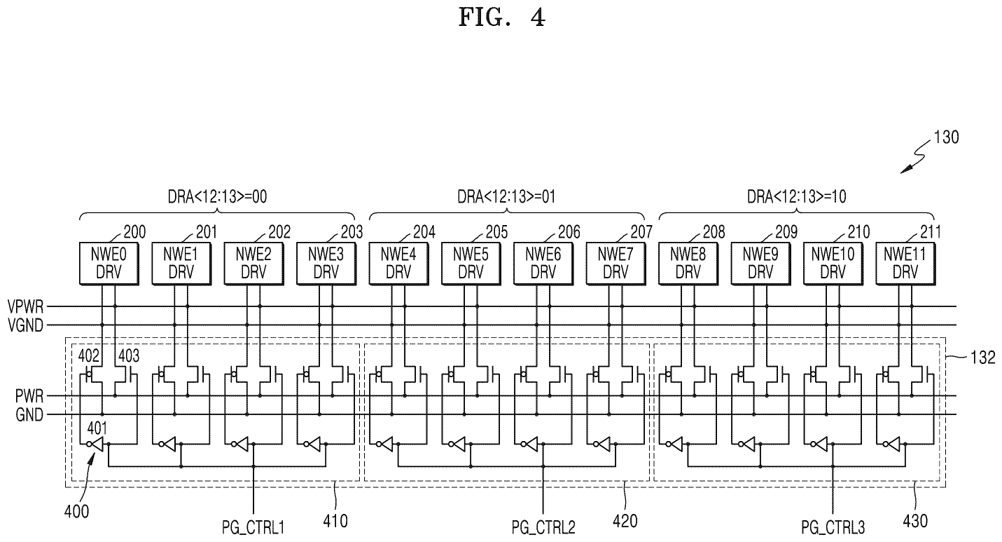

FIG. 4 is a diagram illustrating the row decoder 130 according to some example embodiments. Also illustrated is the power gating switch circuit 132 related to the first to twelfth main word line drive signal generation circuits 200 to 211 of the row decoder 130 of FIG. 2. The power gating switch circuit 132 may be connected between the lines of the first power supply voltage VPWR and the first ground voltage VGND of the first to twelfth main word line drive signal generation circuits 200 to 211 and the lines of a power source PWR and a ground source GND (respectively referred to a power supply line and a ground supply line).

Referring to FIG. 4, the row decoder 130 may include the first to twelfth main word line drive signal generation circuits 200 to 211. The first to fourth main word line drive signal generation circuits 200 to 203 may be activated based on the DRA<12:13> row address signal “00”, the fifth to eighth main word line drive signal generation circuits 204 to 207 may be activated based on the DRA<12:13> row address signal “01”, and the ninth to twelfth main word line drive signal generation circuits 208 to 211 may be activated based on the DRA<12:13> row address signal “11”.

The power gating switch circuit 132 may include a first switch circuit 410, a second switch circuit 420, and a third switch circuit 430. The first switch circuit 410 may be configured to respectively connect the lines of the power source PWR and the ground source GND to the lines of the first power supply voltage VPWR and the first ground voltage VGND of the first to fourth main word line drive signal generation circuits 200 to 203 in response to the first control signal PG_CTRL1. The second switch circuit 420 may be configured to respectively connect the lines of the power source PWR and the ground source GND to the lines of the first power supply voltage VPWR and the first ground voltage VGND of the fifth to eighth main word line drive signal generation circuits 204 to 207 in response to the second control signal PG_CTRL2. The third switch circuit 430 may be configured to respectively connect the lines of the power source PWR and the ground source GND to the lines of the first power supply voltage VPWR and the first ground voltage VGND of the ninth to twelfth main word line drive signal generation circuits 208 to 211 in response to the third control signal PG_CTRL3.

In some example embodiments, the line of the power source PWR may include a line of a high voltage VPP generated by a voltage generation circuit of the memory device 100. In some example embodiments, the line of the power source PWR may include a line of the negative voltage VBB generated by the voltage generation circuit, an internal power supply voltage line, a reference voltage line, and the like.

Each of the first to third switch circuits 410 to 430 may include a plurality of switch circuit units 400. Each of the first to third switch circuits 410 to 430 may be turned on by corresponding one of the first to third control signals PG_CTRL1, PG_CTRL2, and PG_CTRL3. Each of the switch circuit units 400 may include an inverter 401 receiving corresponding one of the first to third control signals PG_CTRL1, PG_CTRL2, and PG_CTRL3, a first power gating element 402 connected between the line of the power source PWR and the line of the first power supply voltage VPWR, and a second power gating element 403 connected between the line of the ground source GND and the line of the first ground voltage VGND. The first power gating element 402 may include a PMOS transistor turned on or off by an output signal of the inverter 401. The second power gating element 403 may include an NMOS transistor turned on or off by corresponding one of the first to third control signals PG_CTRL1, PG_CTRL2, and PG_CTRL3.

For example, when the first control signal PG_CTRL1 at a logic high level is provided to each switch circuit unit 400 of the first switch circuit 410, the first and second power gating elements 402 and 403 may be turned on, and thus, the power source PWR and the ground source GND may be respectively provided to the lines of the first power supply voltage VPWR and the first ground voltage VGND of the first to fourth main word line drive signal generation circuits 200 to 203. When the first control signal PG_CTRL1 at a logic low level is provided to the switch circuit unit 400 of the first switch circuit 410, the first and second power gating elements 402 and 403 may be turned off, and thus, supply of the power source PWR and the ground source GND respectively to the lines of the first power supply voltage VPWR and the first ground voltage VGND of the first to fourth main word line drive signal generation circuits 200 to 203 may be interrupted.

When the second control signal PG_CTRL2 at a logic high level is provided to each switch circuit unit 400 of the second switch circuit 420, the first and second power gating elements 402 and 403 may be turned on, and thus, the power source PWR and the ground source GND may be respectively provided to the lines of the first power supply voltage VPWR and the first ground voltage VGND of the fifth to eighth main word line drive signal generation circuits 204 to 207. When the second control signal PG_CTRL2 at a logic low level is provided to the switch circuit unit 400 of the second switch circuit 420, the first and second power gating elements 402 and 403 may be turned off, and thus, supply of the power source PWR and the ground source GND respectively to the lines of the first power supply voltage VPWR and the first ground voltage VGND of the fifth to eighth main word line drive signal generation circuits 204 to 207 may be interrupted.

When the third control signal PG_CTRL3 at a logic high level is provided to each switch circuit unit 400 of the third switch circuit 430, the first and second power gating elements 402 and 403 may be turned on, and thus, the power source PWR and the ground source GND may be respectively provided to the lines of the first power supply voltage VPWR and the first ground voltage VGND of the ninth to twelfth main word line drive signal generation circuits 208 to 211. When the third control signal PG_CTRL3 at a logic low level is provided to the switch circuit unit 400 of the third switch circuit 430, the first and second power gating elements 402 and 403 may be turned off, and thus, supply of the power source PWR and the ground source GND respectively to the lines of the first power supply voltage VPWR and the first ground voltage VGND of the ninth to twelfth main word line drive signal generation circuits 208 to 211 may be interrupted.

As described above, the power gating switch circuit 132 may reduce power consumption by placing one or more of the first to twelfth main word line drive signal generation circuits 200 to 211 of the row decoder 130 in a powered-off (or a reduced power) state.

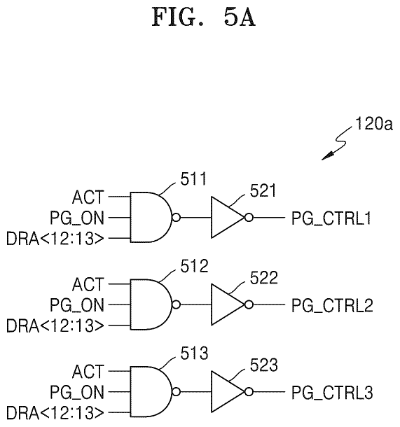

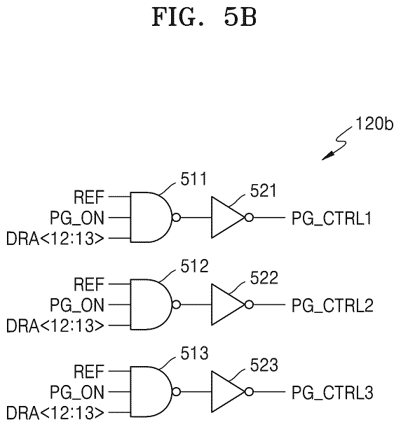

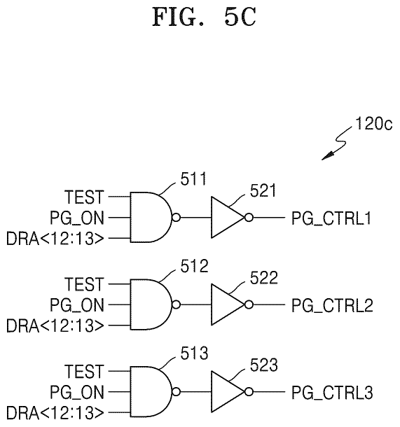

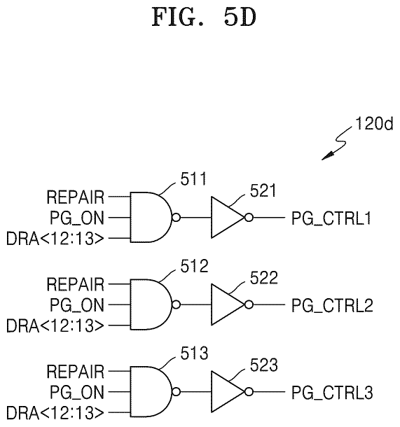

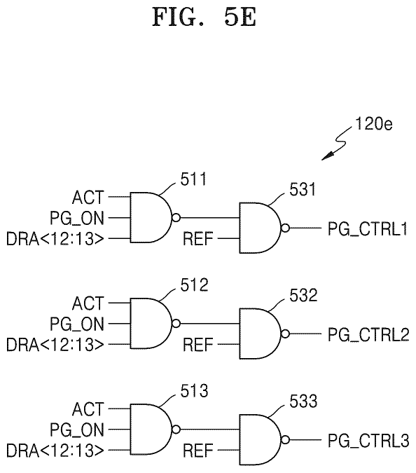

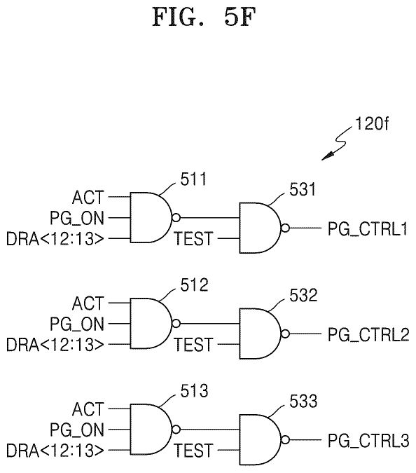

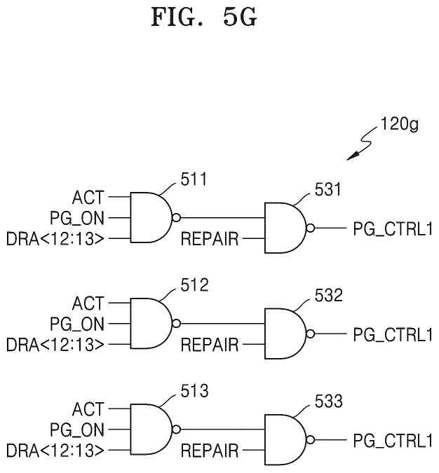

FIGS. 5A to 5G are diagrams illustrating control logic circuits according to some example embodiments. Described below are various examples of the control logic circuit 120 in FIG. 1, which generates the first to third control signals PG_CTRL1, PG_CTRL2, and PG_CTRL3 for respectively controlling the first switch circuit 410, the second switch circuit 420, and the third switch circuit 430 of the power gating switch circuit 132 in FIG. 4. In the drawings, suffix of a reference numeral (e.g., “a” in 120a or “b” in 120b) is used to distinguish from other elements having the same or similar functions. The control logic circuits 120b to 120g of FIGS. 5B-5G may be same as or similar in some respects to the control logic circuit 120a of FIG. 5A, and therefore may be best understood with reference thereto where like numerals indicate like elements not described again in detail.

Referring to FIG. 5A, the control logic circuit 120a may generate the first to third control signals PG_CTRL1, PG_CTRL2, and PG_CTRL3 in response to an active signal ACT, the power gating on signal PG_ON, and a DRA<12:13> row address signal. The active signal ACT may be provided based on an active command operand captured by the CA circuit 122 in FIG. 1. The power gating on signal PG_ON may be provided from the MRS 121 of the memory device 100. The control logic circuit 120a may include first to third NAND gates 511, 512, and 513 each receiving the active signal ACT, the power gating on signal PG_ON, and the DRA<12:13> row address signal, a first inverter 521 receiving an output of the first NAND gate 511 and outputting the first control signal PG_CTRL1, a second inverter 522 receiving an output of the second NAND gate 512 and outputting the second control signal PG_CTRL2, and a third inverter 523 receiving an output of the third NAND gate 513 and outputting the third control signal PG_CTRL3.

In some example embodiments, when the active signal ACT and the power gating on signal PG_ON are activated to a logic high level, the control logic circuit 120a may output the first control signal PG_CTRL1 at a logic high level and the second and third control signals PG_CTRL2 and PG_CTRL3 at a logic low level according to a DRA<12:13> row address signal “00”. Accordingly, the first switch circuit 410 may be turned on, and the power source PWR and the ground source GND may be respectively provided to the lines of the first power supply voltage VPWR and the first ground voltage VGND of the first to fourth main word line drive signal generation circuits 200 to 203. The second switch circuit 420 may be turned off, and supply of the power source PWR and the ground source GND to the fifth to eighth main word line drive signal generation circuits 204 to 207 may be interrupted. The third switch circuit 430 may be turned off, and supply of the power source PWR and the ground source GND to the ninth to twelfth main word line drive signal generation circuits 208 to 211 may be interrupted.

In some example embodiments, when the active signal ACT and the power gating on signal PG_ON are activated to a logic high level, the control logic circuit 120a may output the second control signal PG_CTRL2 at a logic high level and the first and third control signals PG_CTRL1 and PG_CTRL3 at a logic low level according to a DRA<12:13> row address signal “01”. Accordingly, the second switch circuit 420 may be turned on, and the power source PWR and the ground source GND may be respectively provided to the lines of the first power supply voltage VPWR and the first ground voltage VGND of the fifth to eighth main word line drive signal generation circuits 204 to 207. The first switch circuit 410 may be turned off, and supply of the power source PWR and the ground source GND to the first to fourth main word line drive signal generation circuits 200 to 203 may be interrupted. The third switch circuit 430 may be turned off, and supply of the power source PWR and the ground source GND to the ninth to twelfth main word line drive signal generation circuits 208 to 211 may be interrupted.

In some example embodiments, when the active signal ACT and the power gating on signal PG_ON are activated to a logic high level, the control logic circuit 120a may output the third control signal PG_CTRL3 at a logic high level and the first and second control signals PG_CTRL1 and PG_CTRL2 at a logic low level according to a DRA<12:13> row address signal “10”. Accordingly, the third switch circuit 430 may be turned on, and the power source PWR and the ground source GND may be respectively provided to the lines of the first power supply voltage VPWR and the first ground voltage VGND of the ninth to twelfth main word line drive signal generation circuits 208 to 211. The first switch circuit 410 may be turned off, and supply of the power source PWR and the ground source GND to the first to fourth main word line drive signal generation circuits 200 to 203 may be interrupted. The second switch circuit 420 may be turned off, and supply of the power source PWR and the ground source GND to the fifth to eighth main word line drive signal generation circuits 204 to 207 may be interrupted.

Referring to FIG. 5B, the control logic circuit 120b may be same as or similar in some respects to the control logic circuit 120a of FIG. 5A and may receive a refresh signal REF instead of the active signal ACT. The refresh signal REF may be provided based on a refresh command operand captured by the CA circuit 122 in FIG. 1. The control logic circuit 120b may generate the first to third control signals PG_CTRL1, PG_CTRL2, and PG_CTRL3 in response to the refresh signal REF, the power gating on signal PG_ON, and the DRA<12:13> row address signal.

Referring to FIG. 5C, the control logic circuit 120c may be same as or similar in some respects to the control logic circuit 120a of FIG. 5A and may receive a test signal TEST instead of the active signal ACT. The test signal TEST may be provided when the memory device 100 operates in a test mode to test the memory cell array 110. The control logic circuit 120c may generate the first to third control signals PG_CTRL1, PG_CTRL2, and PG_CTRL3 in response to the test signal TEST, the power gating on signal PG_ON, and the DRA<12:13> row address signal.

Referring to FIG. 5D, the control logic circuit 120d may be same as or similar in some respects to the control logic circuit 120a of FIG. 5A and may receive a repair signal REPAIR instead of the active signal ACT. During a test operation or other operations of the memory device 100, a defective cell may be detected among memory cells in a memory cell array, and the defective cell may be replaced with a redundancy cell in the memory cell array. The repair signal REPAIR may be provided when the memory device 100 operates in a repair mode to replace a defective cell or defective cells with a redundancy cell or redundancy cells in the memory cell array 110. The control logic circuit 120d may generate the first to third control signals PG_CTRL1, PG_CTRL2, and PG_CTRL3 in response to the repair signal REPAIR, the power gating on signal PG_ON, and the DRA<12:13> row address signal.

Referring to FIG. 5E, the control logic circuit 120e may include the first to third NAND gates 511, 512, and 513 each receiving the active signal ACT, the power gating on signal PG_ON, and the DRA<12:13> row address signal, a fourth NAND gate 531 receiving the output of the first NAND gate 511 and the refresh signal REF and outputting the first control signal PG_CTRL1, a fifth NAND gate 532 receiving the output of the second NAND gate 512 and the refresh signal REF and outputting the second control signal PG_CTRL2, and a sixth NAND gate 533 receiving the output of the third NAND gate 513 and the refresh signal REF and outputting the third control signal PG_CTRL3.

In some example embodiments, when the active signal ACT, the power gating on signal PG_ON, and the refresh signal REF are activated to a logic high level, the control logic circuit 120e may output the first control signal PG_CTRL1 at a logic high level and the second and third control signals PG_CTRL2 and PG_CTRL3 at a logic low level according to the DRA<12:13> row address signal “00”. Accordingly, the first switch circuit 410 may be turned on, and the power source PWR and the ground source GND may be respectively provided to the lines of the first power supply voltage VPWR and the first ground voltage VGND of the first to fourth main word line drive signal generation circuits 200 to 203. The second switch circuit 420 may be turned off, and supply of the power source PWR and the ground source GND to the fifth to eighth main word line drive signal generation circuits 204 to 207 may be interrupted. The third switch circuit 430 may be turned off, and supply of the power source PWR and the ground source GND to the ninth to twelfth main word line drive signal generation circuits 208 to 211 may be interrupted.

In some example embodiments, when the active signal ACT, the power gating on signal PG_ON, and the refresh signal REF are activated to a logic high level, the control logic circuit 120e may output the second control signal PG_CTRL2 at a logic high level and the first and third control signals PG_CTRL1 and PG_CTRL3 at a logic low level according to the DRA<12:13> row address signal “01”. Accordingly, the second switch circuit 420 may be turned on, and the power source PWR and the ground source GND may be respectively provided to the lines of the first power supply voltage VPWR and the first ground voltage VGND of the fifth to eighth main word line drive signal generation circuits 204 to 207. The first switch circuit 410 may be turned off, and supply of the power source PWR and the ground source GND to the first to fourth main word line drive signal generation circuits 200 to 203 may be interrupted. The third switch circuit 430 may be turned off, and supply of the power source PWR and the ground source GND to the ninth to twelfth main word line drive signal generation circuits 208 to 211 may be interrupted.

In some example embodiments, when the active signal ACT, the power gating on signal PG_ON, and the refresh signal REF are activated to a logic high level, the control logic circuit 120e may output the third control signal PG_CTRL3 at a logic high level and the first and second control signals PG_CTRL1 and PG_CTRL2 at a logic low level according to the DRA<12:13> row address signal “10”. Accordingly, the third switch circuit 430 may be turned on, and the power source PWR and the ground source GND may be respectively provided to the lines of the first power supply voltage VPWR and the first ground voltage VGND of the ninth to twelfth main word line drive signal generation circuits 208 to 211. The first switch circuit 410 may be turned off, and supply of the power source PWR and the ground source GND to the first to fourth main word line drive signal generation circuits 200 to 203 may be interrupted. The second switch circuit 420 may be turned off, and supply of the power source PWR and the ground source GND to the fifth to eighth main word line drive signal generation circuits 204 to 207 may be interrupted.

Referring to FIG. 5F, the control logic circuit 120f may be same as or similar in some respects to the control logic circuit 120e of FIG. 5E and may receive the test signal TEST instead of the refresh signal REF in FIG. 5E. The control logic circuit 120f may generate the first to third control signals PG_CTRL1, PG_CTRL2, and PG_CTRL3 in response to the active signal ACT, the test signal TEST, the power gating on signal PG_ON, and the DRA<12:13> row address signal.

Referring to FIG. 5G, the control logic circuit 120g may be same as or similar in some respects to the control logic circuit 120e of FIG. 5E and may receive the repair signal REPAIR instead of the refresh signal REF in FIG. 5E. The control logic circuit 120G may generate the first to third control signals PG_CTRL1, PG_CTRL2, and PG_CTRL3 in response to the active signal ACT, the repair signal REPAIR, the power gating on signal PG_ON, and the DRA<12:13> row address signal.

FIGS. 6A and 6B are block diagrams illustrating the column decoder 140 in FIG. 1. The memory block BLK1 may include, for example, 8K bit lines BL according to the configuration of thirteen column address signals CA<0:12>. However, this is just an example and example embodiments are not limited thereto. In some example embodiments, the memory block BLK1 may include 16K or 32K bit lines BL according to the configuration of (or based on) fourteen column address signals CA<0:13> or fifteen column address signals CA<0:14>.

Referring to FIGS. 6A and 6B, the 8K bit lines BL of the memory block BLK1 may be connected to a bit line sense amplifier circuit 600. The bit line sense amplifier circuit 600 may sense a voltage level of bit lines BL connected to a selected word line WL. The column decoder 140 may include eight column selection line drivers, e.g., first to eighth column selection line drivers (CSL DRV0-CSL DRV7) 610, 620, 630, 640, 650, 660, 670, and 680, each selecting a bit line BL corresponding to the decoded column address DCA with respect to every of 1K bit lines BL that have been sensed. Each of the first to eighth column selection line drivers 610, 620, 630, 640, 650, 660, 670, and 680 may be addressed by signals, e.g., a CA<10:12> column address, in an MSB group among column address signals CA<0:12>. The CA<10:12> column address may be decoded by the CA circuit 122 and provided to the first to eighth column selection line drivers 610, 620, 630, 640, 650, 660, 670, and 680 as a decoded column address (expressed as a DCA<10:12> column address).

The first to eighth column selection line drivers 610, 620, 630, 640, 650, 660, 670, and 680 may include first driver circuits 611, 621, 631, 641, 651, 661, 671, and 681, respectively, and second driver circuits 612, 622, 632, 642, 652, 662, 672, and 682, respectively. Each of the first driver circuits 611, 621, 631, 641, 651, 661, 671, and 681 and the second driver circuits 612, 622, 632, 642, 652, 662, 672, and 682 is connected to the line of the first power supply voltage VPWR and the line of the first ground voltage VGND. Each of the first driver circuits 611, 621, 631, 641, 651, 661, 671, and 681 and each of the second driver circuits 612, 622, 632, 642, 652, 662, 672, and 682 may select a bit line corresponding to a DCA<0:9> column address from among the 1K sensed bit lines BL. The first driver circuits 611, 621, 631, 641, 651, 661, 671, and 681 may be activated based on a DCA<9> column address signal “0”. The second driver circuits 612, 622, 632, 642, 652, 662, 672, and 682 may be activated based on a DCA<9>column address signal “1”. The DCA<9> column address signal may refer to an MSB signal among the column address signals CA<0:12> obtained by excluding the CA<10:12> column address for the first to eighth column selection line drivers 610, 620, 630, 640, 650, 660, 670, and 680.

Although it is described in some example embodiments that each of the first to eighth column selection line drivers 610, 620, 630, 640, 650, 660, 670, and 680 includes two driver circuits, e.g., one of the first driver circuits 611, 621, 631, 641, 651, 661, 671, and 681 and one of the second driver circuits 612, 622, 632, 642, 652, 662, 672, and 682, this is just an example for sake of explanation and example embodiments are not limited thereto. In some example embodiments, each of the first to eighth column selection line drivers 610, 620, 630, 640, 650, 660, 670, and 680 may include four driver circuits addressed by a DCA<8:9> column address.

The power gating switch circuit 142 may be connected between the lines of the first power supply voltage VPWR and the first ground voltage VGND of the first driver circuits 611, 621, 631, 641, 651, 661, 671, and 681 and the second driver circuits 612, 622, 632, 642, 652, 662, 672, and 682 of the first to eighth column selection line drivers 610, 620, 630, 640, 650, 660, 670, and 680 and the lines of the power source PWR and the ground source GND. The power gating switch circuit 142 may include first switch circuits 601a to 608a respectively connected to the first driver circuits 611, 621, 631, 641, 651, 661, 671, and 681 and second switch circuits 601b to 608b respectively connected to the second driver circuits 612, 622, 632, 642, 652, 662, 672, and 682. In some example embodiments, the line of the power source PWR may include a line of an internal power supply voltage generated by the voltage generation circuit of the memory device 100.

For example, each of the first switch circuit 601a and the second switch circuit 601b may include a switch circuit unit 400 that may be turned on by corresponding one of the first and second control signals PG_CTRLa and PG_CTRLb. As described above with reference to FIG. 4, each of the switch circuit units 400 may include the inverter 401 receiving the first or second control signal PG_CTRLa or PG_CTRLb, the first power gating element 402 connected between the line of the power source PWR and the line of the first power supply voltage VPWR, and the second power gating element 403 connected between the line of the ground source GND and the line of the first ground voltage VGND.

The first switch circuit 601a connected to the first column selection line driver 610 may be configured to respectively connect the lines of the power source PWR and the ground source GND to the lines of the first power supply voltage VPWR and the first ground voltage VGND of the first driver circuit 611 in response to the first control signal PG_CTRLa. The second switch circuit 601b connected to the first column selection line driver 610 may be configured to respectively connect the lines of the power source PWR and the ground source GND to the lines of the first power supply voltage VPWR and the first ground voltage VGND of the second driver circuit 612 in response to the second control signal PG_CTRLb. The first switch circuit 602a connected to the second column selection line driver 620 may be configured to respectively connect the lines of the power source PWR and the ground source GND to the lines of the first power supply voltage VPWR and the first ground voltage VGND of the first driver circuit 621 in response to the first control signal PG_CTRLa. The second switch circuit 602b connected to the second column selection line driver 620 may be configured to respectively connect the lines of the power source PWR and the ground source GND to the lines of the first power supply voltage VPWR and the first ground voltage VGND of the second driver circuit 622 in response to the second control signal PG_CTRLb. The first switch circuit 603a connected to the third column selection line driver 630 may be configured to respectively connect the lines of the power source PWR and the ground source GND to the lines of the first power supply voltage VPWR and the first ground voltage VGND of the first driver circuit 631 in response to the first control signal PG_CTRLa. The second switch circuit 603b connected to the third column selection line driver 630 may be configured to respectively connect the lines of the power source PWR and the ground source GND to the lines of the first power supply voltage VPWR and the first ground voltage VGND of the second driver circuit 632 in response to the second control signal PG_CTRLb.

Similarly, the first switch circuit 607a connected to the seventh column selection line driver 670 may be configured to respectively connect the lines of the power source PWR and the ground source GND to the lines of the first power supply voltage VPWR and the first ground voltage VGND of the first driver circuit 671 in response to the first control signal PG_CTRLa. The second switch circuit 607b connected to the seventh column selection line driver 670 may be configured to respectively connect the lines of the power source PWR and the ground source GND to the lines of the first power supply voltage VPWR and the first ground voltage VGND of the second driver circuit 672 in response to the second control signal PG_CTRLb. The first switch circuit 608a connected to the eighth column selection line driver 680 may be configured to respectively connect the lines of the power source PWR and the ground source GND to the lines of the first power supply voltage VPWR and the first ground voltage VGND of the first driver circuit 681 in response to the first control signal PG_CTRLa. The second switch circuit 608b connected to the eighth column selection line driver 680 may be configured to respectively connect the lines of the power source PWR and the ground source GND to the lines of the first power supply voltage VPWR and the first ground voltage VGND of the second driver circuit 682 in response to the second control signal PG_CTRLb. The power gating switch circuit 142 may similarly include first switch circuits 604a, 605a, and 606a connected to the seventh, eighth, and ninth column selection line drivers 640, 650, and 660, respectively, and second switch circuits 604b, 605b, and 606b connected to the seventh, eighth, and ninth column selection line drivers 640, 650, and 660, respectively. Each of the first switch circuits 604a, 605a, and 606a may be configured to respectively connect the lines of the power source PWR and the ground source GND to the lines of the first power supply voltage VPWR and the first ground voltage VGND of the respective first driver circuits 641, 651, and 661 in response to the first control signal PG_CTRLa. Each of the second switch circuits 604b, 605b, and 606b may be configured to respectively connect the lines of the power source PWR and the ground source GND to the lines of the first power supply voltage VPWR and the first ground voltage VGND of the respective second driver circuits 642, 652, and 662 in response to the first control signal PG_CTRLb. A detailed description thereof is omitted herein for the sake of brevity.

For example, when the first control signal PG_CTRLa at a logic high level is provided to the switch circuit unit 400 included in each of the first switch circuits 601a to 608a, the first and second power gating elements 402 and 403 may be turned on, and thus, the power source PWR and the ground source GND may be respectively supplied to the lines of the first power supply voltage VPWR and the first ground voltage VGND of each of the first driver circuits 611 to 681. When the first control signal PG_CTRLa at a logic low level is provided to the switch circuit unit 400 included in each of the first switch circuits 601a to 608a, the first and second power gating elements 402 and 403 may be turned off, and thus, supply of the power source PWR and the ground source GND respectively to the lines of the first power supply voltage VPWR and the first ground voltage VGND of each of the first driver circuits 611 to 681 may be interrupted.

When the second control signal PG_CTRLb at a logic high level is provided to the switch circuit unit 400 included in each of the second switch circuits 601b to 608b, the first and second power gating elements 402 and 403 may be turned on, and thus, the power source PWR and the ground source GND may be respectively supplied to the lines of the first power supply voltage VPWR and the first ground voltage VGND of each of the second driver circuits 612 to 682. When the second control signal PG_CTRLb at a logic low level is provided to the switch circuit unit 400 included in each of the second switch circuits 601b to 608b, the first and second power gating elements 402 and 403 may be turned off, and thus, supply of the power source PWR and the ground source GND respectively to the lines of the first power supply voltage VPWR and the first ground voltage VGND of each of the second driver circuits 612 to 682 may be interrupted.

As described above, the power gating switch circuit 142 may reduce power consumption by placing the first driver circuits 611, 621, 631, 641, 651, 661, 671, and 681 or the second driver circuits 612, 622, 632, 642, 652, 662, 672, and 682 of the first to eighth column selection line drivers 610, 620, 630, 640, 650, 660, 670, and 680 in a powered-off (or reduced power) state.

In some example embodiments, each of the first to eighth column selection line drivers 610, 620, 630, 640, 650, 660, 670, and 680 may include first to fourth driver circuits addressed by a DCA<8:9> column address. The power gating switch circuit 142 may include first to fourth switch circuits respectively connected to the first to fourth driver circuits. This may mean that the power source PWR and the ground source GND are supplied to only one of the first to fourth driver circuits and are not supplied to the other driver circuits according to the DCA<8:9> column address. Accordingly, power consumption may be reduced by placing some (e.g., one or more) of the driver circuits of each of the first to eighth column selection line drivers 610, 620, 630, 640, 650, 660, 670, and 680 in a powered-off state.

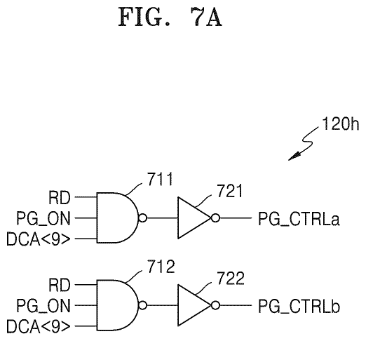

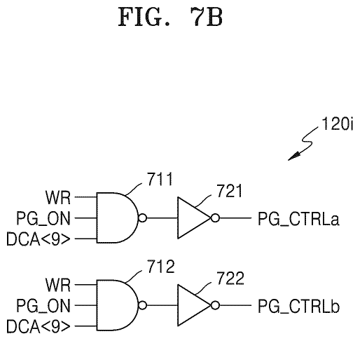

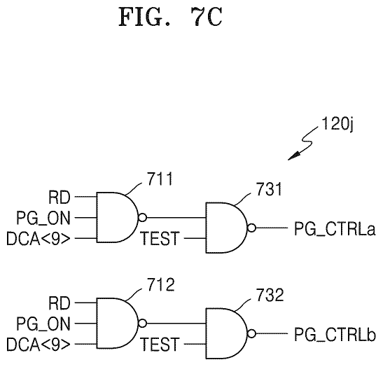

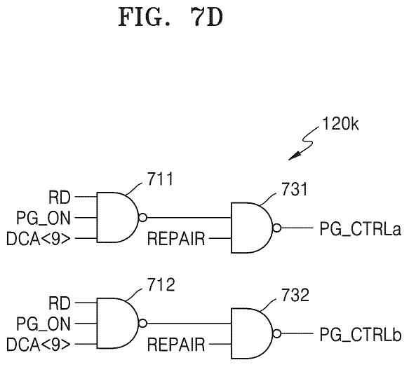

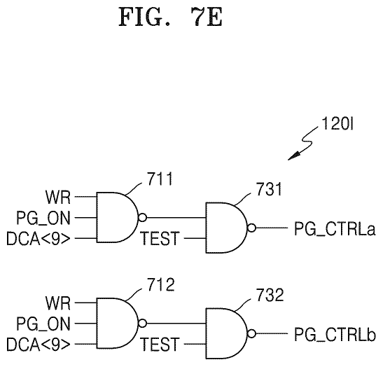

FIGS. 7A to 7E are diagrams illustrating control logic circuits according to embodiments. Described below are various examples of the control logic circuit 120 in FIG. 1, which generates the first control signal PG_CTRLa for controlling the first switch circuits 601a to 608a of the power gating switch circuit 142 in FIGS. 6A and 6B and the second control signal PG_CTRLb for controlling the second switch circuits 601b to 608b of the power gating switch circuit 142 in FIGS. 6A and 6B.

Referring to FIG. 7A, a control logic circuit 120h may generate the first control signal PG_CTRLa and the second control signal PG_CTRLb in response to a read signal RD, the power gating on signal PG_ON, and the DCA<9> column address signal. The read signal RD may be provided based on a read command operand captured by the CA circuit 122 in FIG. 1. The control logic circuit 120h may include first and second NAND gates 711 and 712 each receiving the read signal RD, the power gating on signal PG_ON, and the DCA<9> column address signal, a first inverter 721 receiving an output of the first NAND gate 711 and outputting the first control signal PG_CTRLa, and a second inverter 722 receiving an output of the second NAND gate 712 and outputting the second control signal PG_CTRLb.

In some example embodiments, when the read signal RD and the power gating on signal PG_ON are activated to a logic high level, the control logic circuit 120h may output the first control signal PG_CTRLa at a logic high level and the second control signal PG_CTRLb at a logic low level according to the DCA<9> column address signal “0”. Accordingly, the first switch circuits 601a to 608a may be turned on, and the power source PWR and the ground source GND may be respectively provided to the lines of the first power supply voltage VPWR and the first ground voltage VGND of the first driver circuits 611, 621, 631, 641, 651, 661, 671, and 681. The second switch circuits 601b to 608b may be turned off, and supply of the power source PWR and the ground source GND to the second driver circuits 612, 622, 632, 642, 652, 662, 672, and 682 may be interrupted.

In some example embodiments, when the read signal RD and the power gating on signal PG_ON are activated to a logic high level, the control logic circuit 120h may output the first control signal PG_CTRLa at a logic low level and the second control signal PG_CTRLb at a logic high level according to the DCA<9> column address signal “1”. Accordingly, the second switch circuits 601b to 608b may be turned on, and the power source PWR and the ground source GND may be respectively provided to the lines of the first power supply voltage VPWR and the first ground voltage VGND of the second driver circuits 612, 622, 632, 642, 652, 662, 672, and 682. The first switch circuits 601a to 608a may be turned off, and supply of the power source PWR and the ground source GND to the first driver circuits 611, 621, 631, 641, 651, 661, 671, and 681 may be interrupted.

Referring to FIG. 7B, a control logic circuit 120i may be same as or similar in some respects to the control logic circuit 120h of FIG. 7A and may receive a write signal WR that may be provided based on a write command operand captured by the CA circuit 122 in FIG. 1. The control logic circuit 120i may generate the first control signal PG_CTRLa and the second control signal PG_CTRLb in response to the write signal WR, the power gating on signal PG_ON, and the DCA<9> column address signal.

Referring to FIG. 7C, a control logic circuit 120j may include the first and second NAND gates 711 and 712 each receiving the read signal RD, the power gating on signal PG_ON, and the DCA<9> column address signal, a third NAND gate 731 receiving the output of the first NAND gate 711 and the test signal TEST and outputting the first control signal PG_CTRLa, and a fourth NAND gate 732 receiving the output of the second NAND gate 712 and the test signal TEST and outputting the second control signal PG_CTRLb.

In some example embodiments, when the read signal RD, the power gating on signal PG_ON, and the test signal TEST are activated to a logic high level, the control logic circuit 120j may output the first control signal PG_CTRLa at a logic high level and the second control signal PG_CTRLb at a logic low level according to the DCA<9> column address signal “0”. Accordingly, the first switch circuits 601a to 608a may be turned on, and the power source PWR and the ground source GND may be respectively provided to the lines of the first power supply voltage VPWR and the first ground voltage VGND of the first driver circuits 611, 621, 631, 641, 651, 661, 671, and 681. The second switch circuits 601b to 608b may be turned off, and supply of the power source PWR and the ground source GND to the second driver circuits 612, 622, 632, 642, 652, 662, 672, and 682 may be interrupted.

In some example embodiments, when the read signal RD, the power gating on signal PG_ON, and the test signal TEST are activated to a logic high level, the control logic circuit 120j may output the first control signal PG_CTRLa at a logic low level and the second control signal PG_CTRLb at a logic high level according to the DCA<9> column address signal “1”. Accordingly, the second switch circuits 601b to 608b may be turned on, and the power source PWR and the ground source GND may be respectively provided to the lines of the first power supply voltage VPWR and the first ground voltage VGND of the second driver circuits 612, 622, 632, 642, 652, 662, 672, and 682. The first switch circuits 601a to 608a may be turned off, and supply of the power source PWR and the ground source GND to the first driver circuits 611, 621, 631, 641, 651, 661, 671, and 681 may be interrupted.

Referring to FIG. 7D, a control logic circuit 120k may be similar in some respects to the control logic circuit 120j of FIG. 7C and may receive the repair signal REPAIR. The control logic circuit 120k may generate the first control signal PG_CTRLa and the second control signal PG_CTRLb in response to the read signal RD, the power gating on signal PG_ON, the repair signal REPAIR, and the DCA<9> column address signal.

Referring to FIG. 7E, a control logic circuit 120l may be similar in some respects to the control logic circuit 120j of FIG. 7C and may receive receives the write signal WR instead of the read signal RD. The control logic circuit 120l may generate the first control signal PG_CTRLa and the second control signal PG_CTRLb in response to the write signal WR, the power gating on signal PG_ON, the test signal TEST, and the DCA<9> column address signal. For the purposes of discussion herein, the single operation as mentioned in the disclosure may refer to a read operation associated with the read signal RD of FIG. 7A, a write operation associated with the write signal WR of FIG. 7B, a test operation associated with the read signal RD and the test signal TEST of FIG. 7C, a repair operation associated with the repair signal REPAIR of FIG. 7D, or a test operation associated with the write signal WR and the test signal TEST of FIG. 7E.

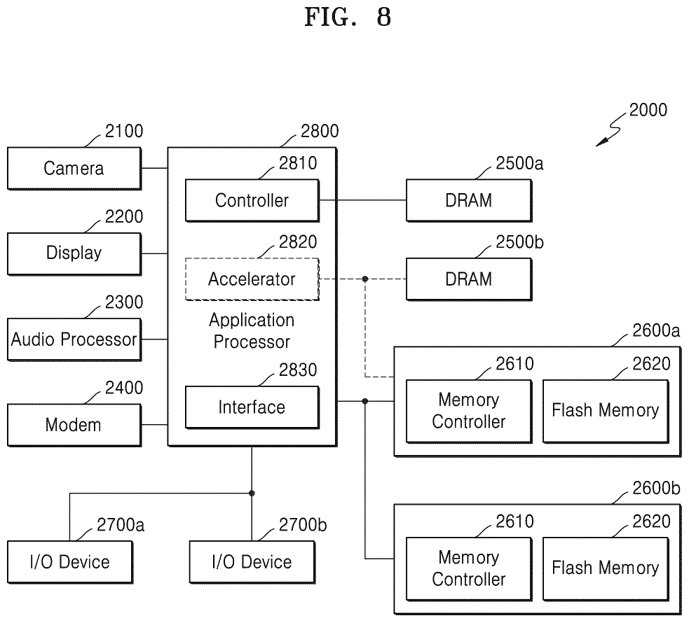

FIG. 8 is a block diagram of a system 2000 illustrating an electronic apparatus including a memory apparatus, according to some example embodiments.

Referring to FIG. 8, the system 2000 may include a camera 2100, a display 2200, an audio processor 2300, a modem 2400, one or more DRAMs 2500a and 2500b (two shown), one or more flash memory devices 2600a and 2600b (two shown), one or more input/output (I/O) devices 2700a and 2700b (two shown), and an application processor (AP) 2800. In some example embodiments, the system 2000 may include a laptop computer, a mobile phone, a smartphone, a tablet personal computer (PC), a wearable device, a healthcare device, or an Internet of things (IoT) device. In some example embodiments, the system 2000 may include a server or a PC.

The camera 2100 may shoot a still image or a video under a user's control and store image/video data and/or transmit the image/video data to the display 2200. The audio processor 2300 may process audio data included in the contents of the flash memory devices 2600a and 2600b or a network. For wired/wireless data communication, the modem 2400 modulates a signal, transmits a modulated signal, and demodulates a received signal to restore an original signal. The I/O devices 2700a and 2700b may include devices, such as universal serial bus (USB) storage, a digital camera, a secure digital (SD) card, a digital versatile disc (DVD), a network adapter, and a touch screen, which provide digital input and/or output functions.

The AP 2800 may control operations of the system 2000. The AP 2800 may include a controller 2810, an accelerator block or accelerator chip 2820, and/or an interface 2830. The AP 2800 may control the display 2200 to display the contents stored in the flash memory devices 2600a and 2600b. When the AP 2800 receives user input through the I/O devices 2700a and 2700b, the AP 2800 may perform a control operation corresponding to the user input. The AP 2800 may include an accelerator block, which may be a dedicated circuit for artificial intelligence (AI) data operations, or the accelerator chip 2820 may be provided separately from the AP 2800. The DRAM 2500b may be additionally mounted on the accelerator block or the accelerator chip 2820. An accelerator may be a functional block that may specially perform a certain function of the AP 2800 and may include a GPU that is a functional block specially performing graphics data processing, a neural processing unit (NPU) that is a functional block specially performing AI calculation and inference, and a data processing unit (DPU) that is a functional block specially performing data transmission. In some example embodiments, an image shot by a user through the camera 2100 may undergo signal processing and may be stored in the DRAM 2500b, and the accelerator block or the accelerator chip 2820 may perform an AI data operation using data stored in the DRAM 2500b and a function used for inference to recognize the data.

The system 2000 may include a plurality of DRAMs 2500a and 2500b. The AP 2800 may control the DRAMs 2500a and 2500b through commands and mode register setting (MRS), which comply with Joint Electron Device Engineering Council (JEDEC) standards, or may set a DRAM interface protocol and communicate with the DRAMs 2500a and 2500b to use company's unique functions, such as low voltage, high speed, reliability, and a cyclic redundancy check (CRC) function, and/or an error correction code (ECC) function. For example, the AP 2800 may communicate with the DRAM 2500a through an interface, such as low power double data rate 4 (LPDDR4) or LPDDR5, complying with the Joint Electron Device Engineering Council (JEDEC) standards, and the accelerator block or the accelerator chip 2820 may set a new DRAM interface protocol and communicate with the DRAM 2500b to control the DRAM 2500b, which has a higher bandwidth than the DRAM 2500a for an accelerator.

Although only the DRAMs 2500a and 2500b are illustrated in FIG. 8, example embodiments are not limited thereto. Any type of memory, such as phase-change RAM (PRAM), static RAM (SRAM), magnetic RAM (MRAM), resistance RAM (RRAM), ferroelectric RAM (FRAM), or hybrid RAM, as may be required depending on a bandwidth, a response speed, and/or a voltage for the AP 2800 or the accelerator chip 2820, may be used. The DRAMs 2500a and 2500b have relatively less latency and bandwidth than the I/O devices 2700a and 2700b or the flash memory devices 2600a and 2600b. The DRAMs 2500a and 2500b may be initialized when the system 2000 is powered on and may be loaded with an operating system (OS) and application data, and may be used as a temporary storage of the OS and the application data and/or may be used as a space for execution of various kinds of software code.

The four arithmetic operations, e.g., addition, subtraction, multiplication, and division, vector operations, address operation, or fast Fourier transform (FFT) operations may be performed in the DRAMs 2500a and 2500b. Functions for executions used for inference may also be performed in the DRAMs 2500a and 2500b. Here, the inference may be performed during a deep learning algorithm using an artificial neural network. The deep learning algorithm may include a training phase, in which a model is trained using various data, and an inference phase, in which data is recognized using the trained model.

The system 2000 may include a plurality of storages or flash memory devices 2600a and 2600b, which have a larger capacity than the DRAMs 2500a and 2500b. The accelerator block or the accelerator chip 2820 may perform a training phase and an AI data operation using the flash memory devices 2600a and 2600b. In some example embodiments, each of the flash memory devices 2600a and 2600b may include a memory controller 2610 and a flash memory 2620 and may allow the AP 2800 and/or the accelerator chip 2820 to efficiently perform a training phase and an inference AI data operation using an arithmetic unit included in the memory controller 2610. The flash memory devices 2600a and 2600b may store images shot through the camera 2100 or data received from a data network. For example, the flash memory devices 2600a and 2600b may store augmented and/or virtual reality contents, high definition (HD) contents, or ultra-high definition (UHD) contents.

In the system 2000, the DRAMs 2500a and 2500b may include a memory device according to some example embodiments described with reference to FIGS. 1 to 7E. The memory device may include a row decoder and a column decoder. The row decoder may include word line driver circuits, which are connected to a plurality of word lines connected to memory cells and select a word line corresponding to decoded row addresses. The row decoder may reduce power consumption by placing some (e.g., one or more) of the word line driver circuits in a powered-off state using a power gating switch circuit. The column decoder may include column selection line drivers selecting bit lines corresponding to a decoded column address with respect to a selected memory block. The column decoder may reduce power consumption by placing some (e.g., one or more) of the column selection line drivers in a powered-off state using a power gating switch circuit. The memory device including the DRAMs 2500a and 2500b may be applied to a high-speed communication device and system, according to some example embodiments.

As described herein, any devices, systems, modules, portions, units, controllers, circuits, and/or portions thereof according to any of the example embodiments, and/or any portions thereof (including, without limitation, the memory cell array 110, the control logic circuit 120, the row decoder 130, the column decoder 140, the mode register set (MRS) 121, the command address (CA) circuit 122, the power gating switch circuit 132, the power gating switch circuit 142, the main word line driver (MWD) circuit 230, the sub word line driver (SWD) circuit 240, the first to twelfth main word line drive signal generation circuits 200 to 211, the bit line sense amplifier circuit 600, the first to eighth column selection line drivers (CSL DRV0-CSL DRV7) 610, 620, 630, 640, 650, 660, 670, and 680, the first driver circuits 611, 621, 631, 641, 651, 661, 671, and 681, the second driver circuits 612, 622, 632, 642, 652, 662, 672, and 682, the camera 2100, the display 2200, the audio processor 2300, the modem 2400, the DRAMs 2500a and 2500b, the flash memory devices 2600a and 2600b, the input/output (I/O) devices 2700a and 2700b, the application processor (AP) 2800, the controller 2810, the accelerator block or accelerator chip 2820, the interface 2830, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several example embodiments have been provided in the present disclosure, it should be understood that the disclosed devices, systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A memory device comprising:
a power source line;
a ground source line;
a row decoder connected to a plurality of word lines connected to memory cells and including word line driver circuits configured to select a word line corresponding to decoded row addresses, the word line driver circuits being configured to be driven by a power supply voltage supplied to a first power supply voltage line and a ground voltage supplied to a first ground voltage line and the word line driver circuits being divided, based on a first most significant bit (MSB) signal, into a first group and a second group, the first MSB signal corresponding to an MSB signal among the decoded row addresses; and
a power gating switch circuit configured to connect the power source line and the ground source line to the first power supply voltage line and the first ground voltage line, respectively, of the word line driver circuits in the first group in response to a first control signal and configured to connect the power source line and the ground source line to the first power supply voltage line and the first ground voltage line, respectively, of the word line driver circuits in the second group in response to a second control signal.

2. The memory device of claim 1, further comprising:
a mode register set (MRS) configured to store a power gating on signal to set a power gating operation of the memory device;
a command address (CA) circuit configured to receive a command address (CA) externally provided to the memory device; and
a control logic circuit configured to generate the first control signal and the second control signal.

3. The memory device of claim 2, wherein the control logic circuit is further configured to,
generate the first control signal and the second control signal in response to an active signal provided from the CA circuit, the power gating on signal provided from the MRS, and the first MSB signal.

4. The memory device of claim 2, wherein the control logic circuit is further configured to,
generate the first control signal and the second control signal in response to a refresh signal provided from the CA circuit, the power gating on signal provided from the MRS, and the first MSB signal.

5. The memory device of claim 2, wherein the control logic circuit is further configured to,
generate the first control signal and the second control signal in response to a test signal provided in a test mode of the memory device, the power gating on signal provided from the MRS, and the first MSB signal.

6. The memory device of claim 2, wherein the control logic circuit is further configured to,
generate the first control signal and the second control signal in response to a repair signal provided in a repair mode that replaces defective cells of the memory device with redundancy cells, the power gating on signal provided from the MRS, and the first MSB signal.

7. The memory device of claim 2, wherein the control logic circuit is further configured to,
generate the first control signal and the second control signal in response to an active signal and refresh signal each provided from the CA circuit, the power gating on signal, and the first MSB signal.

8. The memory device of claim 2, wherein the control logic circuit is further configured to,
generate the first control signal and the second control signal in response to an active signal provided from the CA circuit, a test signal provided in a test mode of the memory device, the power gating on signal, and the first MSB signal.

9. The memory device of claim 2, wherein the control logic circuit is further configured to,
generate the first control signal and the second control signal in response to an active signal provided from the CA circuit, a repair signal provided in a repair mode that replaces defective cells of the memory device with redundancy cells, the power gating on signal, and the first MSB signal.

10. The memory device of claim 2, wherein
the row decoder further includes word line driver circuits in a third group,
the control logic circuit is further configured to generate a third control signal based on the first MSB signal and a second MSB signal, and
the power gating switch circuit is configured to connect the power source line and the ground source line to the first power supply voltage line and the first ground voltage line, respectively, of the word line driver circuits in the third group.

11. A memory device comprising:
a power source line;
a ground source line;
a column decoder connected to a plurality of bit lines connected to memory cells and including column selection line drivers configured to select a bit line corresponding to decoded column addresses, the column selection line drivers each including a first driver circuit and a second driver circuit each configured to be driven by a power supply voltage supplied to a first power supply voltage line and a ground voltage supplied to a first ground voltage line, the first driver circuit and the second driver circuit configured to be activated in response to a first most significant bit (MSB) signal corresponding to an MSB signal among the decoded column addresses obtained by excluding decoded column addresses addressing the column selection line drivers; and
a power gating switch circuit configured to connect the power source line and the ground source line to the first power supply voltage line and the first ground voltage line, respectively, of the first driver circuit in response to a first control signal and configured to connect the power source line and the ground source line to the first power supply voltage line and the first ground voltage line, respectively, of the second driver circuit in response to a second control signal.

12. The memory device of claim 11, further comprising:
a mode register set (MRS) configured to store a power gating on signal to set a power gating operation of the memory device;
a command address (CA) circuit configured to receive a command address (CA) externally provided to the memory device; and
a control logic circuit configured to generate the first control signal and the second control signal.

13. The memory device of claim 12, wherein the control logic circuit is further configured to,
generate the first control signal and the second control signal in response to a read signal provided from the CA circuit, the power gating on signal provided from the MRS, and the first MSB signal.

14. The memory device of claim 12, wherein the control logic circuit is further configured to,
generate the first control signal and the second control signal in response to a write signal provided from the CA circuit, the power gating on signal provided from the MRS, and the first MSB signal.

15. The memory device of claim 12, wherein the control logic circuit is further configured to,
generate the first control signal and the second control signal in response to a read signal provided from the CA circuit, the power gating on signal provided from the MRS, a test signal provided in a test mode of the memory device, and the first MSB signal.

16. The memory device of claim 12, wherein the control logic circuit is further configured to,
generate the first control signal and the second control signal in response to a read signal provided from the CA circuit, the power gating on signal provided from the MRS, a repair signal provided in a repair mode that replaces defective cells of the memory device with redundancy cells, and the first MSB signal.

17. The memory device of claim 12, wherein the control logic circuit is further configured to,
generate the first control signal and the second control signal in response to a write signal provided from the CA circuit, the power gating on signal provided from the MRS, a test signal provided in a test mode of the memory device, and the first MSB signal.

18. A memory device comprising:
first and second power source lines;
first and second ground source lines;
a row decoder connected to a plurality of word lines connected to memory cells and including word line driver circuits configured to select a word line corresponding to decoded row addresses, the word line driver circuits being configured to be driven by a power supply voltage supplied to a first power supply voltage line and a ground voltage supplied to a first ground voltage line, and the word line driver circuits being divided, based on a first most significant bit (MSB) signal, into a first group and a second group, the first MSB signal corresponding to an MSB signal among the decoded row addresses;
a column decoder connected to a plurality of bit lines connected to the memory cells and including column selection line drivers selecting a bit line corresponding to decoded column addresses, the column selection line drivers each including a first driver circuit and a second driver circuit each configured to be driven by the power supply voltage supplied to a second power supply voltage line and the ground voltage supplied to a second ground voltage line, the first driver circuit and the second driver circuit being activated based on a second MSB signal corresponding to an MSB signal among the decoded column addresses obtained by excluding decoded column addresses addressing the column selection line drivers; and
a power gating switch circuit configured to connect the first power source line and the first ground source line to the first power supply voltage line and the first ground voltage line, respectively, of the word line driver circuits in the first group in response to a first control signal, configured to connect the first power source line and the first ground source line to the first power supply voltage line and the first ground voltage line, respectively, of the word line driver circuits in the second group in response to a second control signal, configured to connect the second power source line and the second ground source line to the second power supply voltage line and the second ground voltage line, respectively, of the first driver circuit in response to a third control signal, and configured to connect the second power source line and the second ground source line to the second power supply voltage line and the second ground voltage line, respectively, of the second driver circuit in response to a fourth control signal.

19. The memory device of claim 18, wherein the first control signal and the second control signal are selectively activated based on the first MSB signal.

20. The memory device of claim 18, wherein the third control signal and the fourth control signal are selectively activated based on the second MSB signal.
